(19) United States
(12) Patent Application Publication
(10) Pub. No.: US 2017/0244006 A1
(43) Pub. Date: Aug. 24, 2017

(54) PARALLEL PLATE INLINE SUBSTRATE PROCESSING TOOL

(71) Applicant: APPLIED MATERIALS, INC., Santa Clara, CA (US)

(72) Inventors: BRIAN H. BURROWS, San Jose, CA (US); NILESH BAGUL, Bangalore (IN); SUMEDH ACHARYA, Bangalore (IN); BAHUBALI UPADHYE, Bangalore (IN); LANCE A. SCUDDER, Sunnyvale, CA (US); ROGER N. ANDERSON, Sunnyvale, CA (US)

(21) Appl. No.: 15/506,133

(22) PCT Filed: Sep. 1, 2015
(86) PCT No.: PCT/US2015/047871

§ 371 Date: Feb. 23, 2017

Related U.S. Application Data
(60) Provisional application No. 62/052,955, filed on Sep. 19, 2014.

(51) Int. Cl. H01L 31/18; H01L 21/673; C23C 16/54; C23C 16/458; C23C 16/455; H01L 21/67; C23C 16/44

(52) U.S. Cl. CPC H01L 31/1876; H01L 21/67173; H01L 21/67115; H01L 21/67326; C23C 16/4408; C23C 16/4586; C23C 16/4585; C23C 16/45519; C23C 16/4587; C23C 16/54; C23C 16/45523

(57) ABSTRACT

In some embodiments, an inline substrate processing tool may include a substrate carrier having a plurality of slots configured to retain a plurality of substrates parallel to each other when disposed in the slots, a first substrate processing module and a second substrate processing module disposed in a linear arrangement, wherein each substrate processing module includes an enclosure and a track that supports the substrate carrier and provides a path for the substrate carrier to move linearly through the first and second substrate processing modules, and a first gas cap disposed between the first and second substrate processing modules, wherein the first gas cap includes a first process gas conduit to provide a first process gas to the first substrate processing module, and a second process gas conduit to provide a second process gas to the second substrate processing module.

### FIELD

Embodiments of the present disclosure generally relate to semiconductor processing equipment.

### BACKGROUND

Amorphous and polycrystalline solar cells are limited in their efficiency to convert light into energy. Single crystal high mobility materials are capable of much higher efficiency, but are typically much more expensive. Conventional equipment is designed for semiconductor applications with extreme specifications and with a very high cost involved. However, these systems all have high cost and are not capable of high throughput automation.

To achieve very low cost epitaxial deposition for photovoltaic applications at high throughput, the inventors believe changes other than simply making everything larger are needed. For example, the inventors have observed that single batch reactors are limited in throughput with high cost of materials, consumables, and automation challenges. Very high flow rates of hydrogen, nitrogen, water, and precursors are also used. Furthermore, a large amount of hazardous byproducts are generated when growing thick films.

Continuous reactors have been attempted many times for epitaxial processes but have never been production worthy nor achieved good precursor usage. The major issue is poor film quality which the inventors believe is due to isolation between chambers, metal contamination during processing, and excessive maintenance.

On the other hand, single wafer reactors have very inefficient utilization of precursors and power (electrical) and have lower per wafer throughput. Plus single wafer reactors need complex substrate handling mechanisms. Thus, although single wafer reactors can have very high quality, low metal contamination levels, and good thickness uniformity and resistivity, the cost per wafer is very high to get these results.

Therefore, the inventors have provided embodiments of a substrate processing tool that may provide some or all of high precursor utilization, simple automation, low cost, and a relatively simple reactor design having high throughput and process quality.

### SUMMARY

An inline substrate processing tool and methods or use thereof are provided herein. In some embodiments, an inline substrate processing tool may include a substrate carrier having a plurality of slots configured to retain a plurality of substrates parallel to each other when disposed in the slots, a first substrate processing module and a second substrate processing module disposed in a linear arrangement, wherein each substrate processing module includes an enclosure and a track that supports the substrate carrier and provides a path for the substrate carrier to move linearly through the first and second substrate processing modules, and a first gas cap disposed between the first and second substrate processing modules, wherein the first gas cap includes a first process gas conduit to provide a first process gas to the first substrate processing module, and a second process gas conduit to provide a second process gas to the second substrate processing module.

In some embodiments, a substrate support carrier may include two carrier support walls, a first substrate support rack disposed between and coupled to the two carrier support walls, the first substrate support rack having a plurality of slots configured to retain a first plurality of substrates parallel to each other when disposed in the slots, a second substrate support rack disposed between and coupled to the two carrier support walls, the second substrate support rack having a plurality of slots configured to retain a second plurality of substrates parallel to the first plurality of substrates, and a central alignment rack disposed between and coupled to the two carrier support walls, the central alignment rack configured to align the first and second plurality of substrates.

In some embodiments, a method of depositing a material on a plurality of substrates in an inline epitaxial deposition tool may include providing a substrate carrier to a first module of a plurality of modules, the substrate carrier having a first set of parallel substrates disposed in the substrate carrier, providing a first gas to the first module via a first process gas conduit of a gas cap to perform a first step of an epitaxial deposition process on the first set of substrates in the first module, wherein the first gas is flowed in a first direction across at least one surface of each of the first set of substrates, moving the substrate carrier to a second module of a plurality of modules, and providing a second gas to the second module via a second process gas conduit of the gas cap to perform a second step of an epitaxial deposition process on the first set of substrates in the second module, wherein the first gas is flowed in a second direction across the at least one surface of each of the first set of substrates, wherein the second direction is opposite the first direction.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts an inline substrate processing tool in accordance with some embodiments of the present disclosure.

FIG. 2 is a cross sectional view of a module of an inline substrate processing tool in accordance with some embodiments of the present disclosure.

FIG. 3 is a module of an inline substrate processing tool in accordance with some embodiments of the present disclosure.

FIG. 4A depicts an isometric view of an exemplary vertical parallel plate substrate processing module for use in an inline substrate processing tool in accordance with some embodiments of the present disclosure.

FIG. 4B depicts an isometric view of an exemplary track of a vertical parallel plate substrate processing module for use in an inline substrate processing tool in accordance with some embodiments of the present disclosure.

FIG. 4C depicts a partial isometric view of an exemplary vertical parallel plate substrate processing module for use in an inline substrate processing tool in accordance with some embodiments of the present disclosure.

FIG. 4D depicts a gas cap to provide process gases, isolation gases and/or purge gases to one or more vertical parallel plate substrate processing modules in an inline substrate processing tool in accordance with some embodiments of the present disclosure.

FIG. 5 depicts an isometric view of an exemplary horizontal parallel plate substrate processing module for use in an inline substrate processing tool in accordance with some embodiments of the present disclosure.

FIG. 6 depicts an exemplary carrier that may be used with an inline substrate processing tool in accordance with some embodiments of the present disclosure.

FIG. 7 is a method of depositing a material on a plurality of substrates in an inline epitaxial deposition tool in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of indexed inline substrate processing tools and methods of use thereof are provided herein. The inventive inline substrate processing tool advantageously provides cost effective and simple manufacturability and an energy and cost efficient usage, as compared to conventional substrate processing tools utilized to perform multi-step substrate processes. While not limiting in scope, the inventor believes that the inventive inline substrate processing tool may be particularly advantageous for processing larger size substrates, for example such as 450 mm and larger semiconductor substrates, photovoltaic applications, glass panel substrates, or the like.

In some embodiments consistent with the present disclosure, the parallel plate alternating flow (AF) step and grow system described herein advantageously improves throughput in epitaxial reactor processing by providing a plurality of parallel plate radiant cavities that support a high density of substrates within a small reaction zone to improve gas utilization, optimize power use, and minimize unwanted deposition inside the chamber.

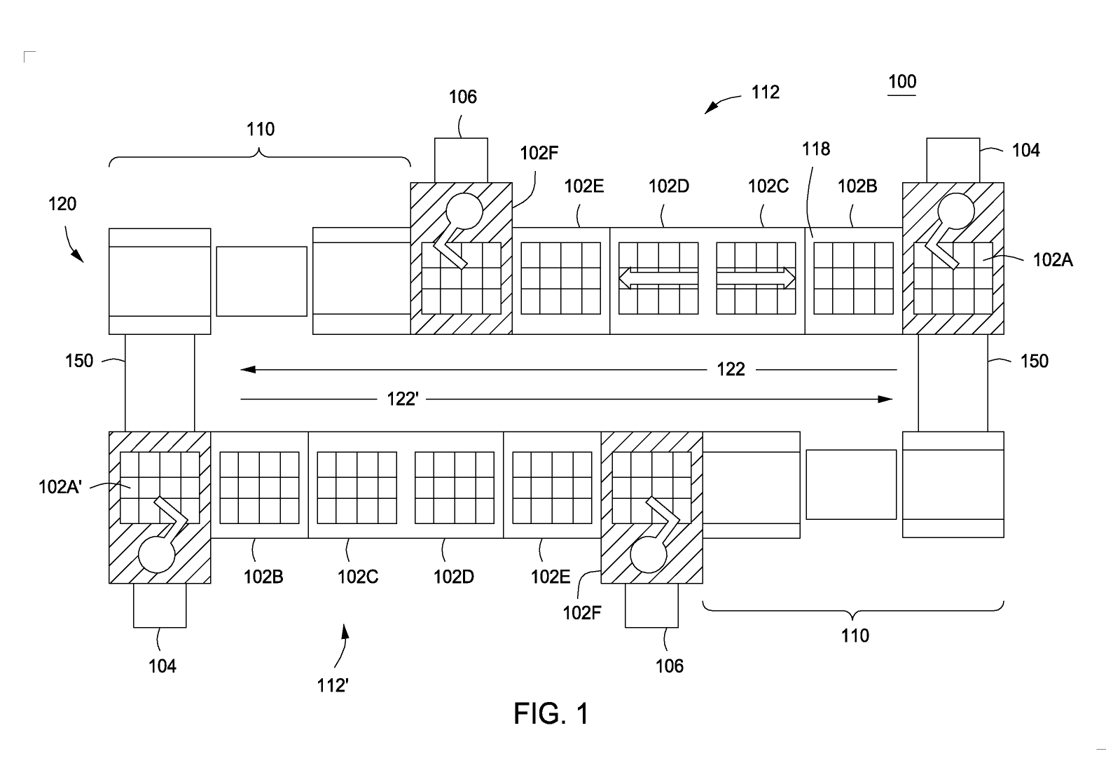

FIG. 1 is an inline substrate processing tool 100 in accordance with some embodiments of the present disclosure. The inline substrate processing tool 100 may generally be configured to perform any process on a substrate for a semiconductor application. For example, in some embodiments, the inline substrate processing tool 100 may be configured to perform one or more deposition processes, such as an epitaxial deposition process.

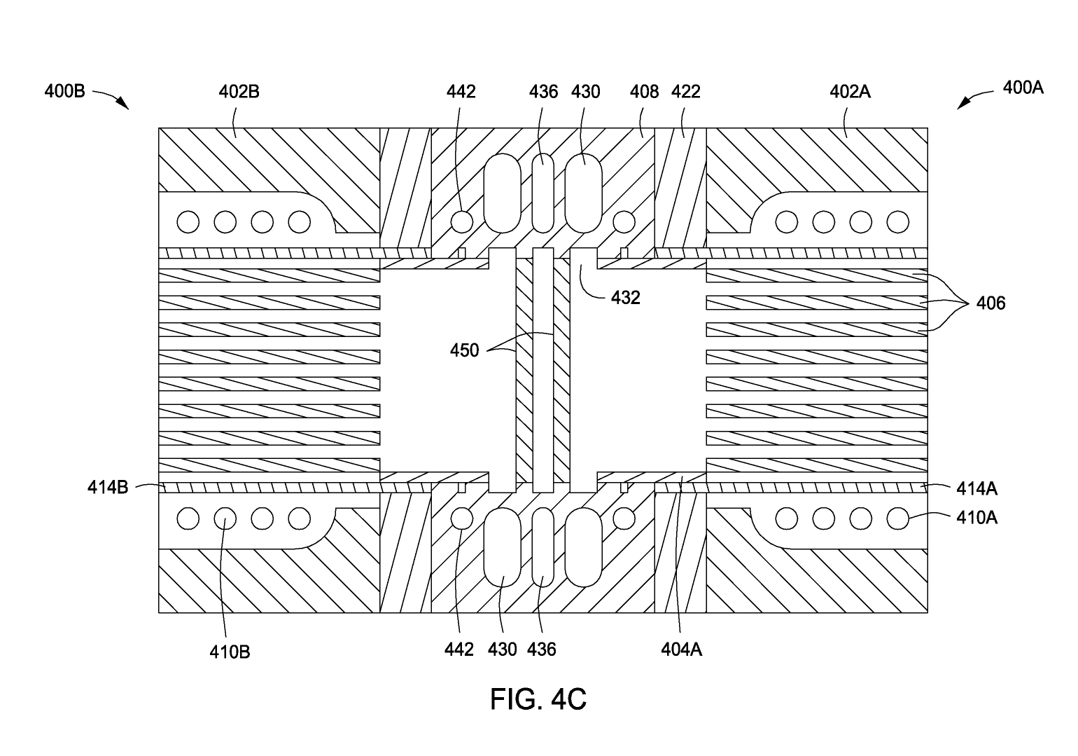

The inline substrate processing tool 100 generally comprises a plurality of modules 112 (first module 102A, second module 102B, third module 102C, fourth module 102D, fifth module 102E, sixth module 102F, and seventh module 102G shown) coupled together in a linear arrangement. In some embodiments, two or more set of modules 112 and 112′, may be coupled together via transfer chambers 150, or raceways, that are configured to transfer a substrate carrier between each set of modules. A substrate may move through the inline substrate processing tool 100 as indicated by the arrows 122 and 122′. In some embodiments, one or more substrates may be disposed on a substrate carrier, for example, such as substrate carriers 404, 504 and 600 described below with respect to FIGS. 4A, 5 and 6 to facilitate movement of the one or more substrates through the inline substrate processing tool 100.

Each of the plurality of modules 112 may be individually configured to perform a portion of a process. By utilizing each of the modules to perform only a portion of a process, each module of the plurality of modules 112 may be specifically configured and/or optimized to operate in a most efficient manner with respect to that portion of the process, thus making the inline substrate processing tool 100 more efficient as compared to conventionally used tools utilized to perform multi-step processes.

In addition, by performing a portion of a process in each module, process resources (e.g., electrical power, process gases, or the like) provided to each module may be determined by the amount of the process resource used only to complete the portion of the process that the module is configured to complete, thus further making the inventive inline substrate processing tool 100 more efficient as compared to conventionally used tools utilized to perform multi-step processes.

In an exemplary configuration of the inline substrate processing tool 100, in some embodiments, the first module 102A may be configured to provide a purge gas to, for example, remove impurities from the substrate and/or substrate carrier and/or introduce the substrate into a suitable atmosphere for deposition. The second module 102B may be configured to preheat or perform a temperature ramp to raise a temperature of the substrate to a temperature suitable for performing the deposition. The second module 102B can also be used to anneal substrates prior to deposition in downstream modules (e.g., third module 102C). The preheat process may occur in a hydrogen environment. In some embodiments, the preheat process may heat the carrier and substrates to a temperature of between 1000 degrees Celsius to about 1500 degrees Celsius.

Next, one or more deposition modules, depicted in FIG. 1 as third module 102C and fourth module 102D, may be configured to deposit a material on the substrate. In some embodiments, another module may be configured to perform a bake to remove volatile impurities from the substrate prior to the deposition of the materials. In some embodiments, the modules 102C and 102D support dual-sided deposition on substrates as will be discussed below in further detail. To achieve deposition and resistivity uniformity in dual-sided parallel plate processing, the gas is flowed across the substrate surfaces in different directions (124 and 124′). For example, as shown in FIG. 1, the process gas is flowed from left to right, depicted by arrow 124, in module 102C and then from right to left, depicted by arrow 124′, in module 102D to achieve the specific uniformity. More specifically, during the deposition process in 102C, the substrates closest to where the deposition gas is introduced would have a thick layer of material deposition, which the substrates disposed near the exhaust would have a thinner layer of material deposition due to depletion of the deposition gas. Thus, a non-uniform epitaxial layer may be formed in the first deposition module (e.g., 102C). Therefore, the deposition gas is flowed in the opposite direction a second deposition module (e.g., 102D) to achieve the desired uniformity. The use of two separate deposition modules to flow the deposition gas advantageously includes a dedicated gas inject and a dedicated gas exhaust which may provide more uniform and predictable particle deposition because the exhaust and inject aren't in kind of close proximity. In addition, the use of two separate deposition modules to flow the deposition gas advantageously simplifies the gas delivery since gas injection in each module may be provided by a common gas injection cap as will be described below in further detail.

In some embodiments, a one or more deposition modules may be used that switches the gas inject and gas exhaust periodically to alternate the gas flow across the substrates within each of the one or more deposition modules. For example, a single deposition module with alternating gas flows may be advantageous in processes where a non-uniform dopant profile is desired.

The fifth module 102E may be configured to cool the substrate. The sixth module 102F may be configured to provide a purge gas to, for example, remove process residues from the substrate and/or substrate carrier prior to removal from the inline substrate processing tool 100. In embodiments where certain processes are not needed, the module configured for that portion of the process may be omitted. For example, if no anneal is needed after deposition, the module configured for annealing may be omitted or may be replaced with a module configured for a different desired process.

Some embodiments of inline substrate processing tool 100 include an inline “pushing mechanism” (now shown) or other mechanism that is able to serially transfer the abutting substrate carriers through modules 102A-102F and 110. For example, indexed transport can use a pneumatic plunger-type push mechanism to drive carrier modules forward through the in-line reactor.

In some embodiments, the barrier 118 may be a gate or door that can open to allow the substrate carrier to move from one module to the next, and can be closed to isolate the module. In some embodiments, the inline substrate processing tool 100 may include both gas curtains and gates, for example, using gas curtains to separate some modules and gates to separate other modules, and/or using gas curtains and gates to separate some modules. Once the push mechanism delivers the substrate carriers to a desired position in each chamber, a door/gate assembly (and chamber liner elements) forms a seal around the substrate carrier to form an enclosed region within each chamber. As the door mechanism is opening or closing a gas flow (i.e., gas purge, or gas curtain) is provided between each door and its adjacent carriers to prevent cross-contamination between chambers. The provided gas flow is received by one or more exhaust ports that are disposed in the bottom of the inline substrate processing tool 100.

In some embodiments, isolation is provided by purge gas curtains using nitrogen, hydrogen or argon gas depending on the location of the gas curtain. For example, the gas curtain in the hotter processing regions would be formed using argon or hydrogen gas. The gas curtains in colder regions near the gates, away from the hotter processing regions, could by nitrogen to minimize cost of operation. The nitrogen gas curtains can only be used in cold, inert sections of each module.

The gate provides additional isolation for certain processes, for example, during the deposition part of the sequence. The gates in hotter regions of the processing system can be made out of quartz to withstand the high temperatures. In order to provide a reflective gate to reflect energy back toward the processing region (and to keep the gate cool), a composite gate can be provided. For example, a polished stainless steel and/or a reflective quartz material may be disposed between two quartz plates.

A load module 104 and an unload module 106 may facilitate providing substrates to, and removing substrates from, the inline substrate processing tool 100, respectively. In some embodiments, the load module 104 and the unload module 106 may provide vacuum pump down and back to atmospheric pressure functions to facilitate transfer of substrates from atmospheric conditions outside of the inline substrate processing tool 100 to conditions within the inline substrate processing tool 100 (which may include vacuum pressures). In some embodiments, the load module 104 and unload module 106 may be part of modules 102A and 102F respectively, or otherwise coupled to modules 102A and 102F. In some embodiments, the load module 104 and unload module 106 would load/unload substrates on a parallel plate carrier in a hydrogen or nitrogen atmosphere so the carrier assembly is not exposed to atmosphere to eliminate outside moisture and other contaminants getting into the system. In some embodiments, one or more substrate carrier transfer robots may be utilized to provide and remove the substrate carrier from the load module 104 and the unload module 106, thus providing an automated loading and unloading of the substrate carrier to and from the inline substrate processing tool 100.

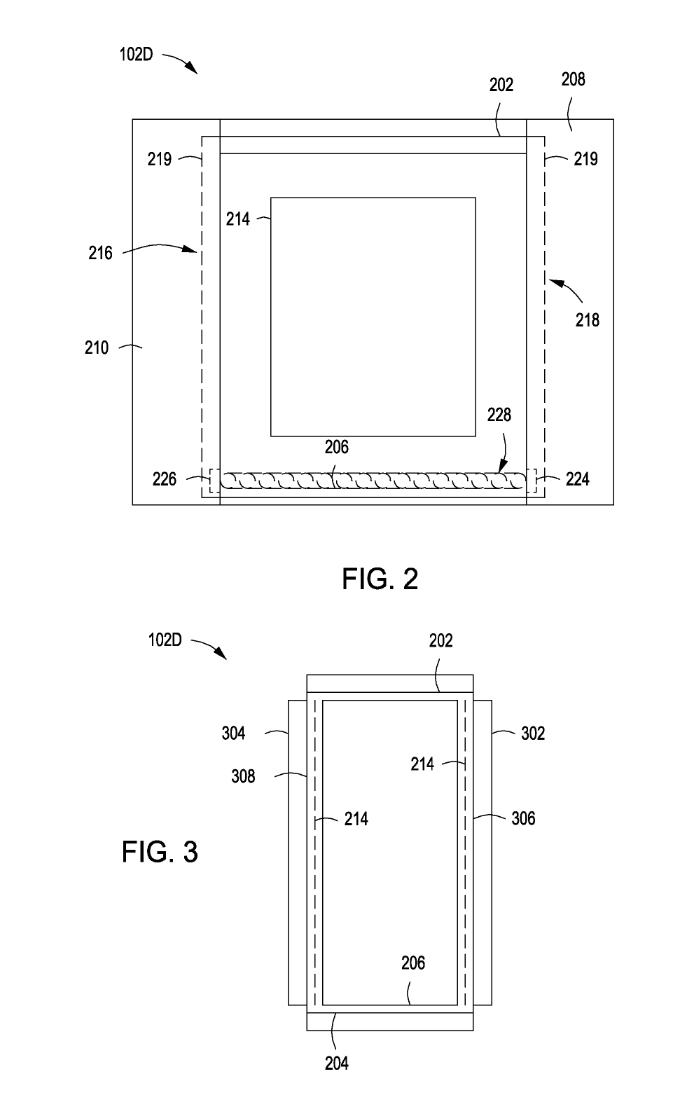

In some embodiments, a track 120, described below with respect to FIG. 2, may be provided along the axial length of the inline substrate processing tool 100 to facilitate guiding the substrate carrier through the inline substrate processing tool 100. The track may be provided along a floor of a facility or other base surface upon which the inline substrate processing tool 100 is mounted. In such embodiments, each module may be configured to be assembled such that the track, may be positioned along an exposed bottom portion of the module to facilitate moving the substrate carrier along the track and through each respective module. Alternatively, the track may be mounted to a bottom surface of the modules once assembled in a linear array. Alternatively, portions of the track 120 may be mounted to a bottom surface of each individual module such that the complete track 120 is formed after assembly of all of the modules in a linear array. In some embodiments, the track 120 may include rollers to facilitate low friction movement of the substrate carrier along the track 120. In some embodiments, the track 120 may be fabricated from or may be coated with a low friction material, such as described below with respect to FIG. 2, to facilitate low friction movement of the substrate carrier along the track 120. In still other embodiments, solid silicon carbide roller bearings may be used as the roller bearing material.

In some embodiments, cleaning modules 110 may be disposed after the unload module 106. When present, the cleaning modules 110 may clean and/or prepare the substrate carrier to receive another one or more substrates for a subsequent run through the inline substrate processing tool 100 (as indicated by the return path arrow 122′). As such, the substrate carriers may be re-used multiple times. In some embodiments, cleaning modules 110 may perform a pre-heat clean and cool-down procedure. The cleaning modules 110 can also be used to pre-coat the carrier assembly with a thin layer of silicon.

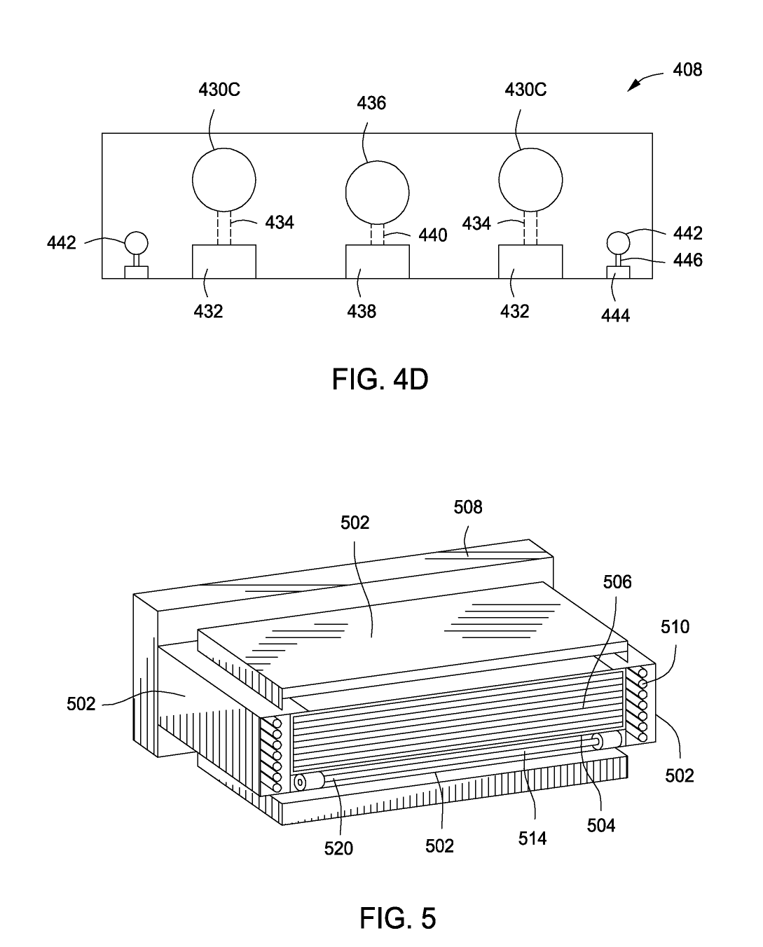

FIG. 2 depicts a cross sectional view of an exemplary configuration of a module, such as module 102D, that may be used as one or more of the modules of the plurality of modules 112 described above, and in some embodiments, as a module configured for the deposition of materials on a substrate. Although generally discussed below in terms of a specific module (102D), the below discussion generally applies to all modules with the exception of components and/or configurations only specifically used for a deposition process. The module 102D may be a vertical module as described with respect to FIG. 4A-4D or a horizontal processing module as described with respect to FIG. 5.

Referring to FIG. 2, in some embodiments, the module 102D may generally include an enclosure 202. The enclosure 202 may be fabricated from any material suitable for semiconductor processing, for example, a metal such as aluminum, stainless steel, or the like. The enclosure 202 may be a reflective housing or have an inner surface that is coated with a reflective coating. The enclosure 202 may have any dimensions suitable to accommodate a parallel plate substrate carrier (e.g., substrate carriers 404 and 504 described below) configured to carry a plurality of parallel substrates of a given size as well as to facilitate a desired flow rate and profile. For example in some embodiments, the enclosure may have a height and length of about 24 inches or about 36 inches and a depth of about 6 inches to about 18 inches. In some embodiments, the enclosure 202 may be assembled by coupling a plurality of plates or sides together to form the enclosure 202. Each enclosure 202 may be configured to form a particular module (e.g., module 102D) that is capable of performing a desired portion of a process. By assembling the enclosure 202 in such a manner, the enclosure 202 may be produced in multiple quantities for multiple applications via a simple and cost effective process.

A lower surface 206 of the enclosure supports the substrate carrier and provides a path for the substrate carrier to move linearly through the module 102D to an adjacent module of the plurality of modules. In some embodiments, the lower surface 206 may be configured as the track 120. In some embodiments, the lower surface 206 may have the track 120, or a portion thereof, coupled to the lower surface 206. In some embodiments, the lower surface 206, or the track 120, may comprise a coating, for example, a dry lubricant such as a nickel alloy (NiAl) containing coating, to facilitate movement of the substrate carrier through the module 102D. Alternatively, or in combination, in some embodiments, a plurality of rollers (shown in phantom at 228) may be disposed above the lower surface 206 to facilitate movement of the substrate carrier through the module 102D. In such embodiments, the plurality of rollers 228 may be fabricated from any material that is non-reactive to the process environment and/or possess suitable thermal management properties, for example, such as quartz (SiO₂).

In some embodiments, a barrier 219 may be disposed proximate the first end 216 and/or second end 218 of the enclosure 202 (e.g., to form the barrier 118 as shown in FIG. 1). When present, the barrier 219 isolates each module of the plurality of modules from an adjacent module to prevent cross contamination or mixing of environments between modules. In some embodiments, the barrier 219 may be a stream of gas, for example a purge gas, provided by a gas inlet (e.g., such as the gas cap 208) disposed at one end of the module 102D. Alternatively, or in combination, in some embodiments, the barrier 219 may be a movable gate. In such embodiments, the gate may be fabricated from a metal, such as aluminum, stainless steel, or the like. In some embodiments, one or more sides of the gate may comprise a reflective coating to minimize heat loss from the module 102D. In some embodiments, one or more notches/features (two notches 224, 226 shown) may be formed in the gate to facilitate securing the substrate carrier in a desired position within the module 102D and/or to form a seal between the substrate carrier and the barrier 219 during processing.

In some embodiments, the module 102D may comprise one or more windows disposed in one or more sides of the enclosure, such as the window 214 disposed in the side 220 of the enclosure 202, as shown in FIG. 2. When present, the window 214 allows radiant heat to be provided into the enclosure 202 from, for example, a radiant heat lamp disposed on a side of the window 214 opposite the interior of the enclosure 202. The window 214 may be fabricated from any material suitable to allow the passage of radiant heat through the window 214 while resisting degradation when exposed to the processing environment within the enclosure 202. For example, in some embodiments, the window 214 may be fabricated from quartz (SiO₂). In some embodiments, window 214 may be a rectangular tube disposed within the enclosure 202 such that parallel plate substrate carrier passes through the rectangular tube.

In some embodiments, the module 102D may include an inject/exhaust gas cap 208 disposed proximate a first end of the module 102D to provide a process gas into the enclosure 202. The gas cap 208 may be configured in any manner suitable to provide a desired process gas flow to the enclosure 202 as described below with respect to FIG. 4C.

Referring back to FIG. 2, in some embodiments, the module 102D may comprise a second gas cap 210 coupled to a portion of the enclosure 202 opposite the first gas cap 208 to facilitate the removal gases from the enclosure 202.

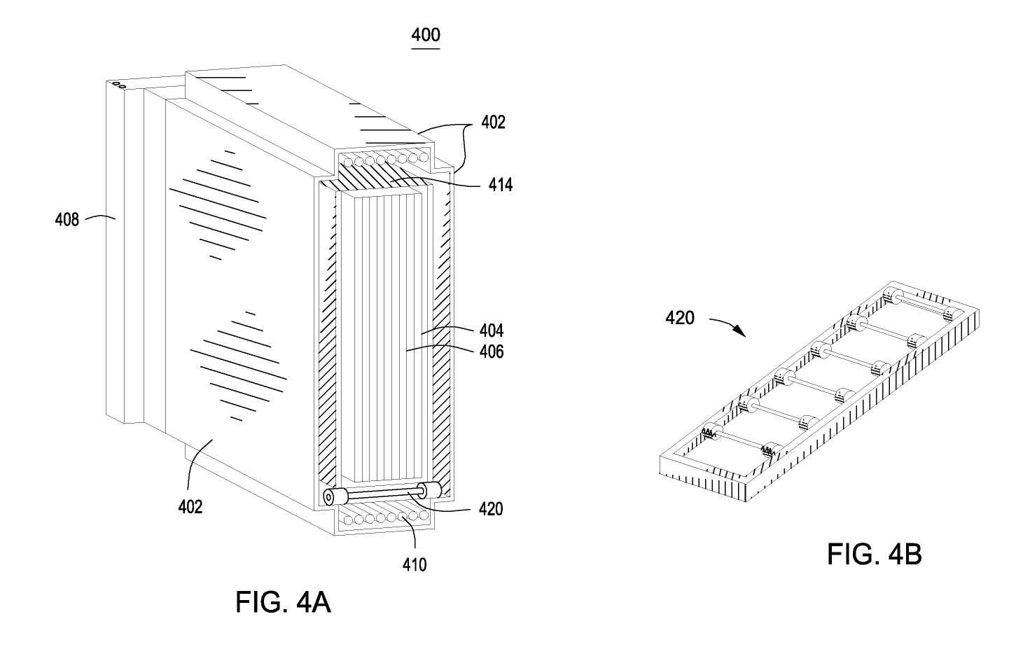

Referring to FIG. 3, in some embodiments, the module 102D may include one or more heating lamps (heating lamps 302, 304 shown) coupled to the sides 306, 308 of the enclosure 202. The heating lamps 302, 304 provide radiant heat into to enclosure 202 via the windows 214. The heating lamps 302, 304 may be any type of heating lamp suitable to provide sufficient radiant heat into the enclosure to perform a desired portion of a process within the module 102D. For example, in some embodiments, the heating lamps 302, 304 may be linear lamps or zoned linear lamps capable of providing radiant heat at a wavelength of about 0.9 microns, or in some embodiments, about 2 microns. The wavelengths used for lamps in various modules may be selected based upon the desired application. For example, the wavelength may be selected to provide a desired filament temperature. Low wavelength bulbs are less expensive, use less power, and can be used for preheating. Longer wavelength bulbs provide high power to facilitate providing higher process temperatures, for example, for deposition processes.

The inline substrate processing tool 100 described above may be oriented vertically or horizontally. FIGS. 4A-4D depict a vertical configuration, while FIG. 5 depicts a horizontal configuration.

FIG. 4A depicts an isometric view of an exemplary vertical parallel plate substrate processing module 400 for use in an inline substrate processing tool 100. The vertical parallel plate substrate processing module 400 includes an enclosure 402 similar to enclosure 202 described above. The enclosure 402 may be a reflective housing that is capable of reflecting radiant heat energy from lamps 410. The lamps 410 may be disposed proximate one or more (e.g., on two surfaces or on four surfaces) inner surfaces of the enclosure 402. The enclosure 402 may include reflectors or a reflective coating (e.g., gold, polished aluminum) disposed on one or more inner surfaces of the enclosure 402. The lamps 410 may be infrared (IR) lamps. In some embodiments that lamps 410 may be tungsten halogen lamp tubes. The enclosure 402 and lamps 410 may be water or air cooled. The enclosure may include a rectangular tube 414, also referred to as a window, which acts as an IR window to pass IR radiant heat energy through to the substrate carrier 404 and substrates 406. The rectangular tube 414 may be fabricated from any material suitable to allow the passage of radiant heat through the rectangular tube 414 while resisting degradation when exposed to the processing environment within the enclosure 402. For example, in some embodiments, the rectangular tube 414 may be fabricated from quartz (SiO₂). The substrate carrier 404 may be supported by track 420 and pass through vertical parallel plate substrate processing module 400 via track 420 which is disposed within the rectangular tube 414. In some embodiments, each of the parallel plates of substrates 406 may be supported at an angle. In some embodiments, each of the substrates 406 may be maintained at an angle of about 1° to about 15° while maintaining the parallel configuration between the substrate 406.

A gas cap 408 provides process gases, isolation gases and/or purge gases to one or more modules in the inline substrate processing tool 100. Specifically, as shown in FIG. 4C, the gas cap 408 may be coupled to vertical modules 400A and 400B via a clamp ring 422. In some embodiments, the clamp ring 422 may be fabricated from stainless steel, a steel alloy, aluminum, or a composite material.

As shown in FIGS. 4C and 4D, the gas cap 408 may include one or inlet conduits 430 to provide process gases to vertical modules 400A and 400B. In some embodiments, the one or more conduits 430 may be fluidly coupled to one or more inlet channels 432 by a plurality of inlet holes 434. The process gases flowed into inlet conduits 430 enter enclosures 402A and 402B. In some embodiments, the one or more of conduits 430 may be exhaust conduits used to remove process gases from enclosures 402A and 402B. The types of processes gases provided may include hydrogen, silicon, carbon, silane, hydrogen chloride (HCl), Trichlorosilane (TCS), and the like.

One or more ceramic gates 450 may be used to separate the modules during processing to avoid cross contamination. The ceramic gates 450 are movable gates that allow substrate carriers 404A and 404B to pass between modules 400A and 400B and other modules. In some embodiments, once a process gas is introduced into enclosure 402A (i.e., via conduit 430, channel 432 and holes 434), for example, the process gas is forced to flow in a first direction between the parallel plates of substrates support by carrier 404A. Similarly, once a process gas is introduced into enclosure 402B, for example, the process gas is forced to flow in a second direction that is opposite the first direction between the parallel plates of substrates support by carrier 404B.

In some embodiments, the gas cap 408 may include isolation gas conduit 436 to provide an isolation gas (i.e., a gas curtain) between ceramic gates 450 to provide for isolation between two connecting modules to prevent cross-contamination. The isolation gas supplied by gas conduit 436 could be a hydrogen or nitrogen purge gas. The isolation gas conduit 436 may be fluidly couple to the space between gates 450 via an isolation gas channel 438 and inlet/outlet holes 440. The isolation gas introduced via gas cap 408 is directed to an opposing gas cap which may exhaust the isolation gas. The types of isolation gases that may be flowed between gates 450 may include hydrogen, nitrogen and other inert gases.

In some embodiments, the gas cap 408 may include window purge gas conduit 442 to provide window purge gases between the carrier 404 and the rectangular tube 414 (i.e., the IR window). The window purge gas conduit 442 may be fluidly coupled to the space between the carrier 404 and the rectangular tube 414 via a window purge channel 444 and inlet/outlet holes 446. The window purge gas introduced via gas cap 408 is forced to flow along the length of the module 400 until it is exhaust by another gas cap 408. The types of window purge gases that may be flowed between the carrier 404 and the rectangular tube 414 may include hydrogen, nitrogen and other inert gases.

FIG. 5 depicts an isometric view of an exemplary horizontal parallel plate substrate processing module 500 for use in an inline substrate processing tool 100. The horizontal parallel plate substrate processing module 500 includes an enclosure 502 similar to enclosures 202 and 402 described above. The enclosure 502 may be a reflective housing that is capable of reflecting radiant heat energy from lamps 510. The enclosure 502 and lamps 510 may be water or air cooled. The enclosure may include a rectangular tube 514, also referred to as a window, which acts as an IR window to pass IR radiant heat energy through to the substrate carrier 504 and substrates 506. The rectangular tube 514 may be fabricated from any material suitable to allow the passage of radiant heat through the rectangular tube 514 while resisting degradation when exposed to the processing environment within the enclosure 502. For example, in some embodiments, the rectangular tube 514 may be fabricated from quartz (SiO₂). The substrate carrier 504 may be supported by a track 520 and pass through horizontal parallel plate substrate processing module 500 via track 520 which is disposed within the rectangular tube 514.

A gas cap 508 provides process gases, isolation gases, and/or purge gases to one or more horizontal modules in the inline substrate processing tool 100 similarly to gas cap 408 described above.

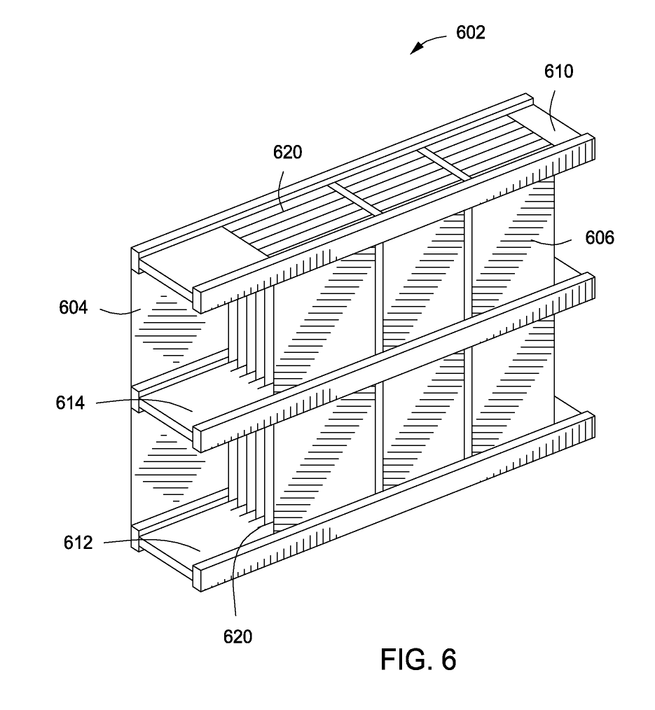

FIG. 6 depicts an exemplary carrier 602 that may be used with the inline substrate processing tool 100 described herein. In some embodiments, the carrier 602 may include ceramic side walls 604. The carrier 602 may also include a top substrate support rack 610, a bottom rack 612, and a center alignment rack 614. The top substrate support rack 610 in the bottom substrate support rack 612 may include slots 620 that support substrates 606. In some embodiments, substrates 606 may be cantilevered such that they are supported only on one end within slots 620. In such embodiments, the center alignment rack 614 may assist in aligning the parallel plates of substrates 606 but do not contact substrate 606. The carrier 602 can support the substrates 606 such that both sides of a substrate may be processed at the same time. In some embodiments, the substrates may be placed on a rack or plate that is supported by slots 620. In some embodiments, each of the parallel plates of substrate 606 may be supported at an angle. In some embodiments, each of the substrates 606 may be maintained at an angle of about 1° to about 15° while maintaining the parallel configuration between the substrate 606. The substrates 406 and 506 shown in FIGS. 4A and 5, respectively, may be similarly supported at an angle.

In some embodiments, the slots 620 disposed in the top, bottom and middle racks 610, 612, 614 allow for gas flow from top to bottom. In addition, although shown in a vertical configuration, carrier 602 may be used in a horizontal module.

In operation of the inline substrate processing tool 100 as described in the above figures, the substrate carrier 602, having a first set of substrates 606 disposed in the substrate carrier 602, is provided to a first module (e.g. first module 102A). When present, a barrier (e.g., barrier 118 or barrier 219) on the first side and/or the second side of the first module may be closed or turned on to facilitate isolating the first module. A first portion of a process (e.g., a purge step of a deposition process) may then be performed on the first set of substrates. After the first portion of the process is complete, a second substrate carrier having a second set of substrates disposed in a second substrate carrier is provided to the first module. As the second substrate carrier is provided to the first module, the second substrate carrier pushes the first carrier to the second module (e.g., the second module 102B). The first portion of the process is then performed on the second set of substrates in the first module while a second portion of the process is performed on the first set of substrates in the second module. The addition of subsequent substrate carriers repeats to provide each substrate carrier to a fixed position (i.e., within a desired module), thus providing a mechanical indexing of the substrate carriers. As the process is completed, the substrate carriers may be removed from the inline substrate processing tool 100 via an unload module (e.g., unload module 106).

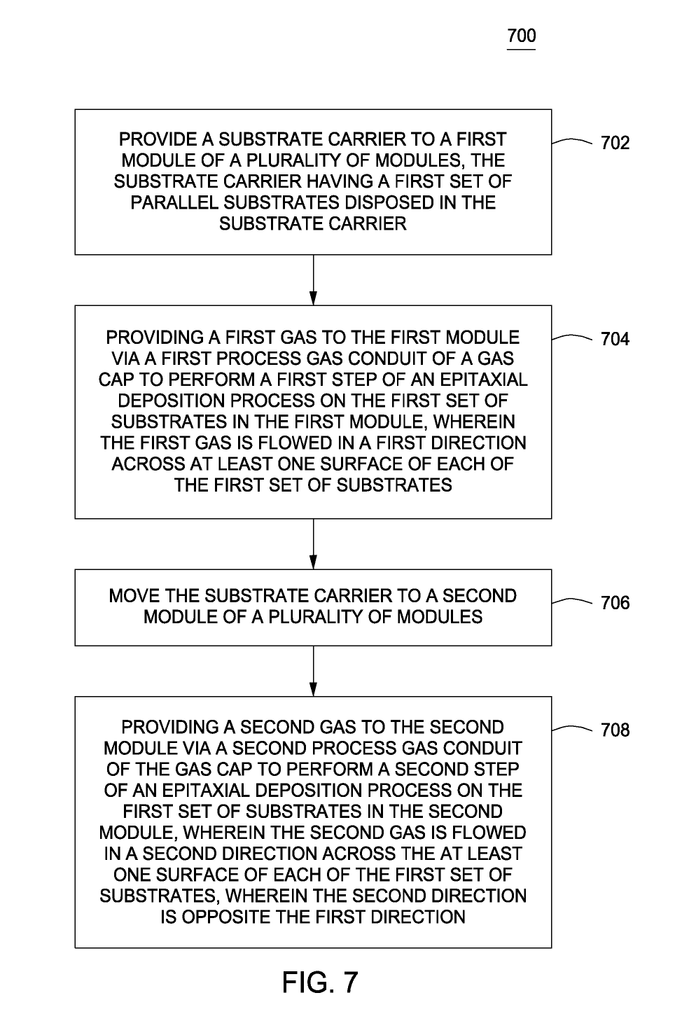

FIG. 7 is a method 700 of depositing a material on a plurality of substrates in an inline epitaxial deposition tool in accordance with some embodiments of the present disclosure. The method 700 begins at 702 where a substrate carrier is provided to a first module of a plurality of modules, the substrate carrier having a first set of parallel substrates disposed in the substrate carrier. At 404, a first gas is flowed/provided into the first module via a first process gas conduit of a gas cap to perform a first step of an epitaxial deposition process on the first set of substrates in the first module. The first gas may be flowed in a first direction across at least one surface of each of the first set of substrates. In some embodiments, the gas may be flowed across a front and back surface or a top and bottom surface depending on orientation of the module and carrier (e.g., horizontal or vertical processing). The substrate carrier is moved to a second module of a plurality of modules at 706. At 708, a second gas is flowed/provided to the second module via a second process gas conduit of the gas cap to perform a second step of an epitaxial deposition process on the first set of substrates in the second module. The second gas is flowed in a second direction across at least one surface of each of the first set of substrates. In some embodiments, the second direction is opposite the first direction. In some embodiments, the first and second gases are the same gas. The first and second gases may be provided such that the first and second gases flow between each of the first set of parallel substrates and over both processing surfaces of each of the first set of parallel substrates. In some embodiments, the method further includes providing, via an isolation gas conduit of the gas cap, an isolation gas between the first and second modules. In some embodiments, the method further includes providing, via a window purge gas conduit of the gas cap, a window purge gas between an outer surface of a window disposed in first and second modules and the substrate carrier.

While the foregoing is directed to embodiments of the present disclosure, other and further embodiments of the disclosure may be devised without departing from the basic scope thereof.

1. An inline substrate processing tool, comprising:
a substrate carrier having a plurality of slots configured to retain a plurality of substrates parallel to each other when disposed in the slots;
a first substrate processing module and a second substrate processing module disposed in a linear arrangement, wherein each substrate processing module includes an enclosure and a track that supports the substrate carrier and provides a path for the substrate carrier to move linearly through the first and second substrate processing modules; and
a first gas cap disposed between the first and second substrate processing modules, wherein the first gas cap includes:
a first process gas conduit to provide a first process gas to the first substrate processing module; and
a second process gas conduit to provide a second process gas to the second substrate processing module.

2. The inline substrate processing tool of claim 1, wherein the first gas cap further comprises an isolation gas conduit to provide an isolation gas between the first and second substrate processing modules.

3. The inline substrate processing tool of claim 2, further comprising:
a second gas cap disposed between the first and second substrate processing modules and opposed to the first gas cap, wherein the second gas cap includes:
a first process gas conduit to provide the first process gas to the first substrate processing module;
a second process gas conduit to provide the second process gas to the second substrate processing module; and
an isolation gas conduit configured to exhaust the isolation gas when provided by the first gas cap.

4. The inline substrate processing tool of claim 3, further comprising a clamp ring that couples the first and second gas caps to the first and second substrate processing modules to form a continuous portion of the inline substrate processing tool.

5. The inline substrate processing tool of claim 1, wherein the first and second substrate processing modules each include:
a window disposed within the enclosure to allow radiant heat to be provided into the enclosure; and
a plurality of heating lamps coupled to a side of the enclosure to provide radiant heat into the enclosure through the window.

6. The inline substrate processing tool of claim 5, wherein the window is a rectangular quartz tube through which the substrate carrier can pass.

7. The inline substrate processing tool of claim 6, wherein the track is disposed proximate a bottom portion of the rectangular quartz tube.

8. The inline substrate processing tool of claim 5, wherein the first gas cap further comprises a window purge gas conduit to provide an window purge gas between an outer surface of the window and the substrate carrier.

9. The inline substrate processing tool of claim 1, wherein the substrate carrier is configured to support substrates in a vertical plane.

10. The inline substrate processing tool of claim 1, wherein the substrate carrier is configured to support substrates in a horizontal plane.

11. The inline substrate processing tool of claim 1, wherein the substrate carrier is configured to support all substrates at a same pre-determined angle.

12. The inline substrate processing tool of claim 1, further comprising:
at least one movable gate disposed between the first and second substrate processing modules.

13. The inline substrate processing tool of claim 1, further comprising:
additional substrate processing modules coupled to the second processing module and disposed in a linear arrangement, wherein each substrate processing module includes an enclosure and a track that supports the substrate carrier and provides a path for the substrate carrier to move linearly through the substrate processing modules.

14. A substrate support carrier, comprising:
two carrier support walls;
a first substrate support rack disposed between and coupled to the two carrier support walls, the first substrate support rack having a plurality of slots configured to retain a first plurality of substrates parallel to each other when disposed in the slots;
a second substrate support rack disposed between and coupled to the two carrier support walls, the second substrate support rack having a plurality of slots configured to retain a second plurality of substrates parallel to the first plurality of substrates; and
a central alignment rack disposed between and coupled to the two carrier support walls, the central alignment rack configured to align the first and second plurality of substrates.

15. A method of depositing a material on a plurality of substrates in an inline epitaxial deposition tool, comprising:
providing a substrate carrier to a first module of a plurality of modules, the substrate carrier having a first set of parallel substrates disposed in the substrate carrier;
providing a first gas to the first module via a first process gas conduit of a gas cap to perform a first step of an epitaxial deposition process on the first set of substrates in the first module, wherein the first gas is flowed in a first direction across at least one surface of each of the first set of substrates;
moving the substrate carrier to a second module of a plurality of modules; and
providing a second gas to the second module via a second process gas conduit of the gas cap to perform a second step of an epitaxial deposition process on the first set of substrates in the second module, wherein the second gas is flowed in a second direction across the at least one surface of each of the first set of substrates, wherein the second direction is opposite the first direction.

16. The method of claim 15, further comprising:
providing, via an isolation gas conduit of the gas cap, an isolation gas between the first and second modules.

17. The method of claim 15, further comprising:
providing, via a window purge gas conduit of the gas cap, a window purge gas between an outer surface of a window disposed in first and second modules and the substrate carrier.

18. The method of claim 15, wherein the first and second gases flow between each of the first set of parallel substrates and over both processing surfaces of each of the first set of parallel substrates.

19. The substrate support carrier of claim 14, wherein the first and second support racks are configured to support all substrates at a same pre-determined angle.

20. The substrate support carrier of claim 14, wherein the two carrier support walls, the first and second support racks, and the central alignment rack are ceramic.
